(19) United States
(12) Patent Application Publication
(10) Pub. No.: US 2009/0241274 A1
(43) Pub. Date: Oct. 1, 2009

(54) METHOD OF REMOVING PARTICLES ON PHOTOMASK

(75) Inventor: Jun Chun, Incheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/347,739

(22) Filed: Dec. 31, 2008

(30) Foreign Application Priority Data
Mar. 27, 2008 (KR) 10-2008-0028636

(51) Int. Cl. G03F 1/00; H01L 21/00

(52) U.S. Cl. 15/1; 15/1.51

(57) ABSTRACT

Provided is a method of removing particles on a photomask. The method includes fabricating a photomask formed with a thin film pattern over a transparent substrate; identifying positions of particles on the photomask by inspecting the photomask; and removing the particles using a nanotweezer.

### CROSS-REFERENCE TO RELATED APPLICATION

Priority to Korean patent application number 10-2008-0028636, filed on Mar. 27, 2008, the disclosure of which is incorporated by reference in its entirety, is claimed.

### BACKGROUND OF THE INVENTION

The present invention relates generally to a photomask, and more particularly, to a method for removing particles on a photomask.

Recently, the size of a pattern formed on a wafer is miniaturized with high integration of semiconductor devices and a photolithography process using a photomask is used to form this miniaturized pattern. According to the photolithography process, a photoresist layer is coated on a material layer to be formed with a pattern and light is exposed onto some of the photoresist layer using a photomask. A photoresist layer pattern is formed by development using developing solution and removal of some of the photoresist layer. A material layer pattern corresponding to the pattern on the photomask can be formed by removing an exposed portion of the material layer with an etch process using the photoresist layer pattern as an etch mask. However, in performing this photolithography process, when there are particles on the photomask, these particles are transferred to the photoresist layer and thus a photoresist layer pattern of a desired profile cannot be formed. Therefore, the particles that may be present on the photomask after fabricating the photomask should be removed.

In general, the removal of the particles is performed using a Focused Ion Beam (FIB) apparatus or Atomic Force Microscope (AFM) lithography apparatus. When using the FIB apparatus, particles are removed as cation is injected from the FIB apparatus and the cations etch the particles. When using the AFM lithography apparatus, a tip of the AFM is moved where there are particles and then image data is obtained. Coordinate values of the particles are obtained using this image data and then the particles are removed by the AFM scratch method.

However, the method using the FIB apparatus may damage the surface of the photomask or affect the pattern on the photomask because the FIB apparatus uses cations. Also, as a critical dimension (CD) of a pattern on the photomask is gradually narrowed with increase in the integration of the semiconductor devices, the FIB apparatus represents a limitation to removing particles caught between the patterns on the photomask. The AFM lithography apparatus generates less surface damage of the photomask compared to the FIB apparatus, but still represents a limitation to removing particles caught between the patterns on the photomask due to the reduction in the pattern CD.

### SUMMARY OF THE INVENTION

Disclosed herein are embodiments directed to methods of removing particles on a photomask that remove fine particles without surface damage of the photomask.

In one embodiment, a method of removing particles on a photomask includes: fabricating a photomask formed with thin film patterns over a transparent substrate; inspecting the photomask to identify a position of a particle on the photomask; and removing the particle using a nanotweezer.

The thin film pattern can include a light blocking layer pattern or a phase shift layer pattern.

Inspecting the photomask can include: inspecting for the presence of particles on an upper portion of the thin film pattern or in a portion where the transparent substrate is exposed between the thin film patterns; and identifying position information of the particles detected by the inspection. The position information can be three-dimensional position information.

Removing the particles using the nanotweezer can include: moving grasping arms of the nanotweezer to the position of the particle; applying a bias to the nanotweezer to make the grasping arms grasp the particle; and separating the particle grasped by the grasping arms from the photomask by moving the nanotweezer away from the photomask.

In another embodiment, a method of removing particles on a photomask includes: inspecting the photomask to detect the presence and position of a particle on the photomask; and removing the particle using a nanotweezer.

The method can further include identifying position information of the particle detected by the inspection. The position information can be three-dimensional position information.

Removing the particles using nanotweezer can include: moving grasping arms of the nanotweezer to the position of the particle; applying a bias to the nanotweezer to make the grasping arms grasp the particle; and separating the particle grasped by the grasping arms from the photomask by moving the nanotweezer away from the photomask.

Because the particles are removed using a nanotweezer, it is possible to remove very fine particles of nanometer scale without surface damage of the photomask.

### BRIEF DESCRIPTION OF THE DRAWINGS

FIGS. 1 through 7 illustrate a method of removing particles on a photomask according to an embodiment of the present invention.

While the disclosed method is susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DESCRIPTION OF SPECIFIC EMBODIMENTS

Disclosed herein is a method of removing particles on a photomask described in detail with reference to the accompanying drawings.

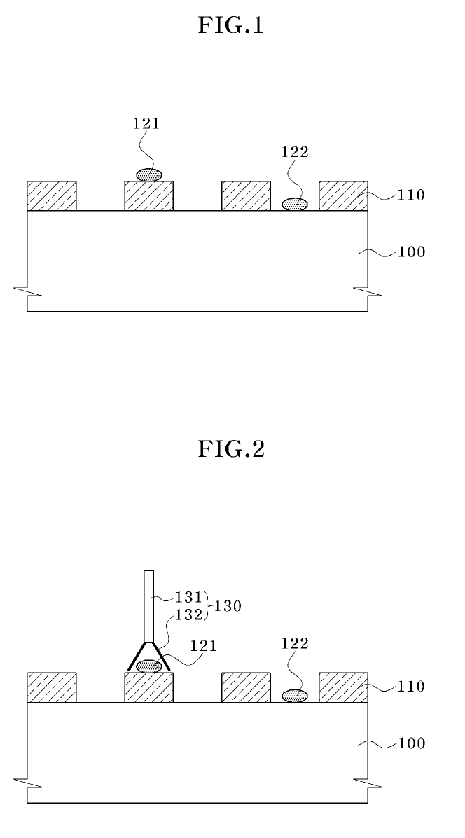

FIGS. 1 through 7 illustrate a method of removing particles on a photomask according to an embodiment of the present invention. As shown in FIG. 1, a photomask is fabricated by forming thin film patterns 110 over a transparent substrate 100, for example, such as quartz. The thin film patterns 110 may be a light blocking layer, such as, for example, a chrome layer, or a phase shift layer, such as, for example, a molybdenum silicon layer. During the fabrication of the photomask, a particle 121 can be generated on the thin film pattern 110 or a particle 122 can be generated on a surface of the transparent substrate 100 between the thin film patterns 110. To remove the particle 121 or the particle 122, the presence of the particle 121 or the particle 122 should first be confirmed.

In an embodiment, an AFM lithography apparatus can be used to detect the presence of the particle 121 or the particle 122. For example, the presence of the particle 121 or the particle 122 is detected by scanning using a tip of the AFM. In this procedure, when the presence of the particle 121 or the particle 122 is detected, data of the exact position of the particle 121 or the particle 122 are obtained by analyzing three dimensional image data obtained during the scanning. Although the presence of the particle 121 or the particle 122 is detected and the position data is obtained using the AFM in the present embodiment, it will be apparent that other apparatuses or methods can also be used.

As shown in FIG. 2, a nanotweezer 130 is moved to the position where the particle 121 is present on the thin film pattern 110. In an embodiment, the nanotweezer 130 has a structure including a pair of grasping arms 132 attached to an end of a support 131. The grasping arms 132 are formed, for example, of a Carbon Nano Tube (CNT), and though not shown, the grasping arms 132 are respectively connected to electrodes.

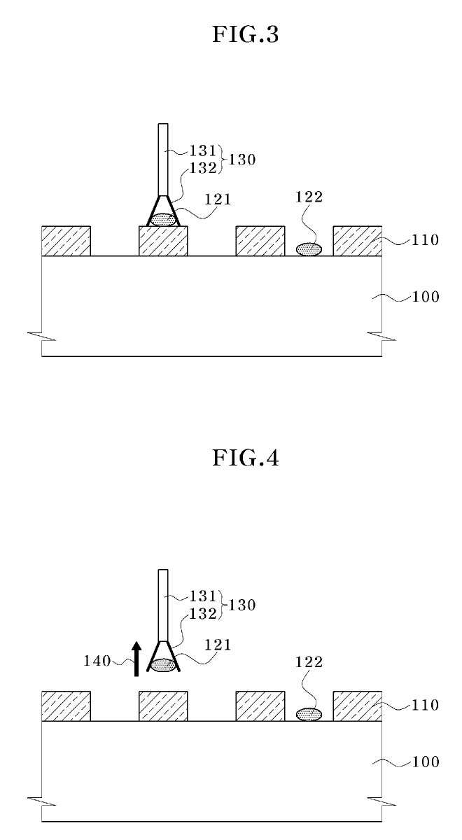

As shown in FIG. 3, the grasping arms 132 of the nanotweezer 130 grasp the particle 121 on the upper portion of the thin film pattern 110. To this end, a voltage bias of a predetermined level is applied to the electrodes connected with the grasping arms 132 of the nanotweezer 130. As the bias voltage increases, the grasping arms of the nanotweezer gradually close. When the bias voltage applied is about 8.5 V or less, preferably less than about 8.3 V, the grasping arms of the nanotweezer relax back to the open position when the bias voltage is removed. For example, a voltage of greater than 0 V and preferably up to 8.3 V, and preferably less than 8.5 V, is applied to the electrodes and the grasping arms 132 attract and bend toward each other, and as a result, the grasping arms 132 firmly physically grasp the particle 121 on the upper portion of the thin film pattern 110. When the voltage applied to the electrodes is more than about 8.5 V, the grasping arms 132 can maintain the closed state even though the voltage bias is stopped, and the particle 121 on the thin film pattern 110 is therefore still in a state of being grasped by the grasping arms 132 of the nanotweezer 130. In this case, the grasping arms in the closed state can be reopened by applying the same polarity of voltage to both sides of the arms.

As shown in FIG. 4, the nanotweezer 130 is moved in a direction of an arrow 140 away from the photomask. As the nanotweezer 130 moves away from the photomask, the particle 121 grasped by the grasping arms 132 of the nanotweezer 130 is separated from the thin film pattern 110 of the photomask and the particle 121 is therefore removed from the photomask.

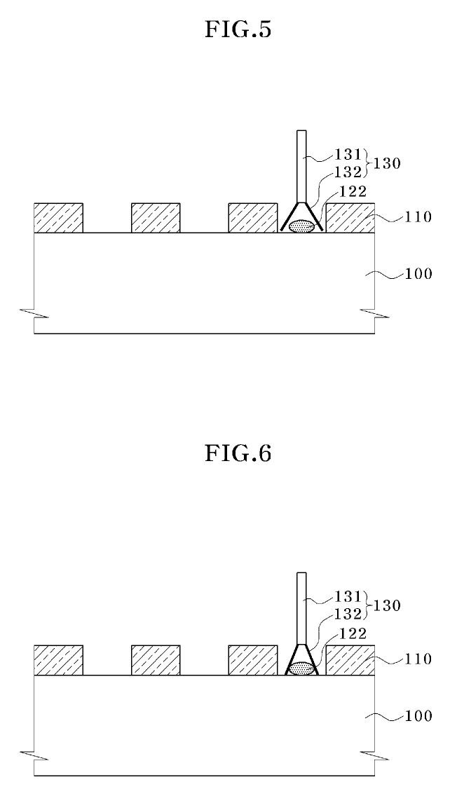

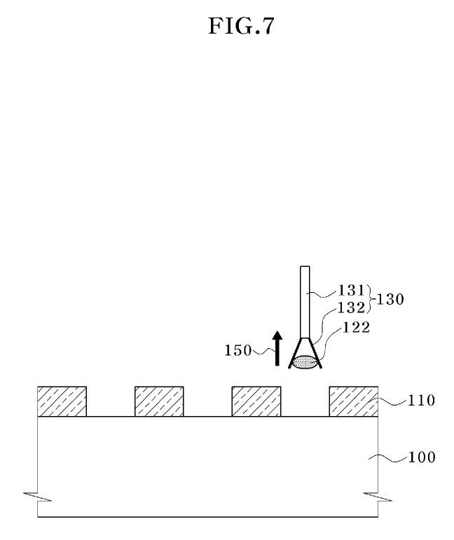

The particle 122 between the thin film patterns 110 can be removed by the same method. The particle 122 can be removed before or after the particle 121 is removed. For example, as shown in FIG. 5, the nanotweezer 130 is moved to the position of the particle 122 between the thin film patterns 110. As shown in FIG. 6, the grasping arms 132 of the nanotweezer 130 grasp the particle 122 between the thin film patterns 110. To this end, a voltage bias of a predetermined level is applied to the electrodes connected with the grasping arms 132 of the nanotweezer 130. For example, a voltage of greater than 0 V and preferably up to 8.3 V, and preferably less than 8.5 V, is applied to the electrodes and the grasping arms 132 attract and bend towards each other, and as a result, the grasping arms 132 firmly grasp the particle 122 between the thin film patterns 110. When the voltage applied to the electrodes is more than about 8.5V, the grasping arms 132 can maintain the closed state even though the voltage bias is stopped, and the particle 122 between the thin film patterns 110 is therefore still in a state of being grasped by the grasping arms 132 of the nanotweezer 130. As shown in FIG. 7, the nanotweezer 130 is moved in a direction of an arrow 150 away from the photomask. As the nanotweezer 130 moves away from the photomask, the particle 122 grasped by the grasping arms 132 of the nanotweezer 130 is separated from the photomask and the particle 122 between the thin film patterns 110 is therefore removed.

While the present invention has been described with respect to the specific embodiments, it will be apparent to those skilled in the art that various changes and modifications may be made without departing from the spirit and scope of the invention as defined in the following claims.

What is claimed is:

1. A method for removing particles on a photomask, the method comprising:
fabricating a photomask having a thin film pattern over a transparent substrate;
inspecting the photomask to detect the presence and position of a particle on the photomask; and
removing the particle using a nanotweezer.

2. The method of claim 1, wherein the thin film pattern comprises a light blocking layer pattern or a phase shift layer pattern.

3. The method of claim 1, wherein the inspecting the photomask comprises:
detecting the presence of a particle on an upper portion of the thin film pattern or in a portion where the transparent substrate is exposed between the thin film pattern.

4. The method of claim 3, further comprising identifying position information of the particle detected by the inspection.

5. The method of claim 4, wherein the position information comprises three-dimensional position information.

6. The method of claim 1, wherein the removing the particle using the nanotweezer comprises:
moving grasping arms of the nanotweezer to the position of the particle;
applying a bias to the nanotweezer to make the grasping arms grasp the particle; and
separating the particle grasped by the grasping arms from the photomask by moving the nanotweezer away from the photomask.

7. The method of claim 6, wherein the bias applied to the nanotweezer is about 8.3 volts or less.

8. The method of claim 6, wherein the bias applied to the nanotweezer is about 8.5 volts or less.

9. The method of claim 6, wherein the bias applied to the nanotweezer is more than about 8.5 volts.

10. A method for removing particles on a photomask, the method comprising:
inspecting the photomask to detect the presence and position of a particle on the photomask; and
removing the particle using a nanotweezer.

11. The method of claim 10, further comprising identifying position information of the particle detected by the inspection.

12. The method of claim 11, wherein the position information comprises three-dimensional position information.

13. The method of claim 10, wherein the removing the particle using the nanotweezer comprises:
moving grasping arms of the nanotweezer to the position of the particle;
applying a bias to the nanotweezer to make the grasping arms grasp the particle; and
separating the particle grasped by the grasping arms from the photomask by moving the nanotweezer away from the photomask.

14. The method of claim 13, wherein the bias applied to the nanotweezer is about 8.3 volts or less.

15. The method of claim 13, wherein the bias applied to the nanotweezer is about 8.5 volts or less.

16. The method of claim 13, wherein the bias applied to the nanotweezer is more than about 8.5 volts.
